(19) United States
(12) Patent Application Publication
(10) Pub. No.: US 2009/0325330 A1
(43) Pub. Date: Dec. 31, 2009

(54) METHOD FOR MANUFACTURING ELECTRON EMITTING DEVICE AND MEMORY MEDIUM OR RECORDING MEDIUM THEREFOR

(75) Inventor: Masaki Kuribayashi, Tokyo (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/369,811

(22) Filed: Feb. 12, 2009

Related U.S. Application Data
(63) Continuation of application No. PCT/JP2008/061753, filed on Jun. 27, 2008.

(51) Int. Cl. H01L 21/20; G06F 19/00

(52) U.S. Cl. 438/20; 700/121; 257/E21.09

(57) ABSTRACT

A method and an apparatus for manufacturing a high intensity electron emitting device using a boron lanthanum compound thin film are provided. An electron emitting base member region is opened in a second substrate disposed with an electron emitting base member, and is applied with a mask screening another region, thereby sputter-accumulating the sputtered particles of a low work function substance target. The second substrate sputter-accumulated and a first substrate disposed with phosphor are sealed by a sealing agent to fabricate a vacuum chamber. During the fabrication step, the first and second substrates are consistently maintained in a vacuum atmosphere or a reduced pressure atmosphere.

### CROSS-REFERENCES TO RELATED APPLICATIONS

This application is a continuation application of International Application No. PCT/JP2008/061753, filed on Jun. 27, 2008, the entire contents of which are incorporated by reference herein.

### TECHNICAL FIELD

The present invention relates to a method for manufacturing a crystalline electron emitting device by a sputtering method using a target having the sintered body of low work function substance, in particular a boron lanthanum compound, and a computer memory medium or recording medium thereof.

### BACKGROUND ART

As disclosed in Patent Documents 1, 2, and 3, as a secondary electron emission film, a thin film of a boron lanthanum compound such as LaB₆ is known. Further, as disclosed in Patent Documents 1, 2, and 3, it is also known that the crystalline thin film of a boron lanthanum compound is deposited by using the sputtering method. Further, as disclosed in Patent Document 4, it is also known that, as a target used by the sputtering method, a sintered body of the boron lanthanum compound such as LaB₆ is used.

Patent Document 1: Japanese Patent Application Laid-Open No. H1-286228

Patent Document 2: Japanese Patent Application Laid-Open No. H3-232959

Patent Document 3: Japanese Patent Application Laid-Open No. H3-101033

Patent Document 4: Japanese Patent Application Laid-Open No. H6-248446

### DISCLOSURE OF THE INVENTION

However, when a boron lanthanum compound thin film is exposed to the atmosphere after the deposition by a sputtering apparatus, it is oxidized. When this oxidized boron lanthanum compound thin film is used for the electron emitting device such as a FED (Field Emission Display) and a SED (Surface-Conduction Electron-emitter Display), it has been hard to obtain sufficient luminance as a display device.

An object of the present invention is to provide an electron emitting device having sufficient luminance using a boron lanthanum compound thin film.

The first aspect of the present invention is a manufacturing method of an electron emitting device, comprising: a first step of preparing a first substrate disposed with phosphors and disposing it in a vacuum or reduced pressure atmosphere; a second step of disposing an electron emitting base member on a second substrate; third step of disposing a mask for opening a first region including said electron emitting base member and screening a second region not including said electron emitting base member, in a state in which a vacuum or reduced pressure atmosphere is maintained from said second step; a fourth step of accumulating sputtered particles on the second substrate subjected to said second step by a sputtering method using a target having a low work function substance in a state in which the vacuum or reduced pressure atmosphere is maintained from said third step; and a fifth step of making the first substrate subjected to said first step oppose to the second substrate subjected to said fourth step and sealing the first substrate and the second substrate by a sealing agent to fabricate a vacuum or reduced pressure chamber, in a state in which the vacuum or reduced pressure atmosphere is maintained from said first step and said fourth step.

The second aspect of the present invention is a memory medium or a recording medium for the manufacturing of an electron emitting device, comprising a control program for executing: a first step of preparing a first substrate disposed with phosphors and disposing it in a vacuum or reduced pressure atmosphere; a second step of disposing an electron emitting base member on a second substrate; a third step of disposing a mask for opening a first region including said electron emitting base member and screening a second region not including said electron emitting base member, in a state in which a vacuum or reduced pressure atmosphere is maintained from said second step; a fourth step of accumulating sputtered particles on the second substrate subjected to said second step by a sputtering method using a target having a low work function substance in a state in which the vacuum or reduced pressure atmosphere is maintained from said third step; and a fifth step of making the first substrate subjected to said first step oppose to the second substrate subjected to said fourth step and sealing the first substrate and the second substrate by a sealing agent to fabricate a vacuum or reduced pressure chamber, in a state in which the vacuum or reduced pressure atmosphere is maintained from said first step and said fourth step.

According to the present invention, the crystalline thin film of a boron lanthanum compound such as LaB₆ can be sealed in a vacuum chamber without being oxidized, thereby a display device having high luminance can be realized.

### BRIEF DESCRIPTION OF THE DRAWINGS

FIG. 1 is a schematic illustration showing a first example of a magnetron sputtering apparatus used for a manufacturing method of a thin film of the present invention;

FIG. 2 is a schematic sectional view of an electron generator of the present invention;

FIG. 3 is a flowchart of the present invention;

FIG. 4 is a block diagram of the present invention;

FIG. 5 is a top plan view of a mask used in the present invention; and

FIG. 6 is a schematic perspective view of an electron emitting device manufactured by the present invention.

### DESCRIPTION OF SYMBOLS

1 First Chamber

2 Second Chamber

5, 51, 52, 53, 54, 55 Gate Valve

11 Target

12 Substrate

13, 15, 42, 43 Substrate Holder

14 Sputter Gas Introducing System

16 Heating Mechanism

17 Plasma Electrode

18 Plasma Source Gas Introducing System

19 Sputtering High Frequency Power Source System

191, 221, 502 Blocking Capacitor

192, 222, 503 Matching Circuit

193, 223, 504 High Frequency Power Source

194 Sputtering DC Power Source (First DC Bias Power Source)

20 (Annealing) Substrate Bias Power Source (Third DC Power Source)

21 Substrate Bias Power Source (Second DC Power Source)

22 Plasma Source High Frequency Power Source System

23, 501 LF Cut Filter for Cutting LF Components from HF Power Source 193

24 HF Cut Filter

101 Cathode

102 Magnetic Field Generator

103 Magnetic Field Region

201, 207 Glass Substrate

202 Cathode Electrode

203 LaB₆ Thin Film

204 Vacuum Space (or Atmosphere)

205 Anode Electrode

206 Phosphor Film

208 Electron Source Substrate

209 Projection

210 Phosphor Substrate

211 DC Power Source

401 Vacuum Mask Loading Apparatus

402 Magnetron Sputtering Apparatus

403 Assemble Device in Vacuum Space

404 First Load Lock Chamber

405, 406, 407, 408, 409 Gate Valve

410 Computer

411 Arithmetic Operation Circuit Unit

413, 414, 415, 416, 417, 418, 419, 420 Control Bus Line

421 Memory Unit

412 Time Control Unit

51 Mask Opening Unit

52 Mask

601 Display-side Substrate

602 Three Primary Color Phosphor Matrix

603 Black Matrix

604 Anode Electrode

605 Spacer

606 Rear Face Substrate

607 Insulator Film

608 Scan Line

609 Signal Line

610 Hole Containing Electron Emitting Device inside thereof

### BEST MODES FOR CARRYING OUT THE INVENTION

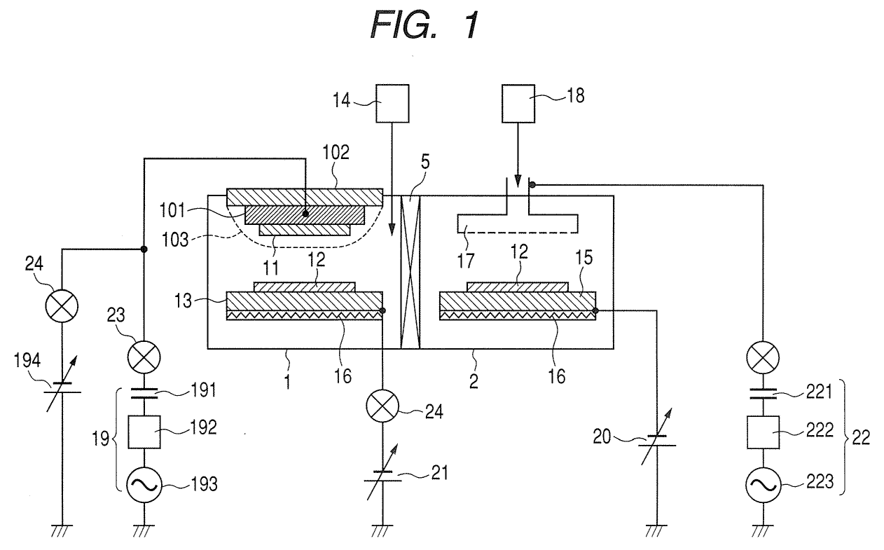

FIG. 1 is a schematic illustration showing a first example of a magnetron sputtering apparatus used in the manufacturing method of a thin film of the present invention. Reference numeral 1 denotes a first chamber, reference numeral 2 a second chamber (annealing unit) connected in vacuum to the first chamber 1, reference numeral 5 a gate valve, reference numeral 11 a sputtering target, reference numeral 12 a substrate, reference numeral 13 a substrate holder (first substrate holder) for holding the substrate 12, reference numeral 14 a sputter gas introducing system, reference numeral 15 a substrate holder (second substrate holder), reference numeral 16 a heating mechanism, reference numeral 17 a plasma electrode, reference numeral 18 a plasma source gas introducing system, reference numeral 19 a sputtering high frequency power source system, reference numeral 101 a cathode loadable with the target 11, reference numeral 102 a magnetic field generator, reference numeral 103 a magnetic field region, reference numeral 191 a blocking capacitor, reference numeral 192 a matching circuit, reference numeral 193 a high frequency power source, reference numeral 194 a sputter bias power source, reference numeral 20 a (annealing) substrate bias power source (third DC power source), reference numeral 21 a substrate bias power source (second DC power source), reference numeral 22 a plasma source high frequency power source system, reference numeral 221 a blocking capacitor, reference numeral 222 a matching circuit, reference numeral 223 a high frequency power source, and reference numeral 23 an LF cut filter (filter) for cutting the LF component from the HF power source 193 so as to be turned into an HF component power. Reference numeral 24 denotes an HF cut filter for cutting the HF component (for example, HF component such as 1 KHz or more, particularly like 1 MHz) contained in the DC power from the DC power sources 21 and 194.

In the present invention, the target 11 containing a boron atom (B) and a lanthanum atom (La) such as LaB₆ is used.

The substrate 12 is placed on the holder 13 inside the first chamber 1, and the substrate 12 is opposed to the cathode 101, and is subjected to vacuum exhaust and heating (increased up to the temperature of the sputtering time later) inside the chamber. The heating is performed by the heating mechanism 16. Next, a plasma source gas (helium gas, argon gas, krypton gas, xenon gas) is introduced from the sputtering gas introducing system 14, and is set to the predetermined pressure (0.01 Pa to 50 Pa, and preferably 0.1 Pa to 10 Pa), and after that, a deposition is started by using the sputter power source 19.

Next, by applying a high frequency power from a high frequency power source 193 (the frequency is 0.1 MHz to 10 GHz, and preferably 1 MHz to 5 GHz, and the input power is 100 W to 3000 W, and preferably 200 W to 2000 W), plasma is generated, and in the first DC power source 194, a DC power (voltage) is set to the predetermined voltage (−50 V to −1000 V, and preferably −10 V to −500 V), thereby to perform a sputter deposition. At the substrate 12 side, the substrate holder 13 is applied with the DC power (voltage) by the predetermined voltage (0 V to −500 V, and preferably −10 V to −100 V) by the second DC power source 21. The DC power (first DC power) from the first DC power source 194 may be inputted before applying the high frequency power from the high frequency power source 193, and may be inputted simultaneously with the application of the high frequency power, and may be continuously inputted after completing the application of the high frequency power.

An input position to the cathode 101 of the DC power and/or the high frequency power from the second DC power source 21 and/or the sputtering high frequency power source 19 is preferably set to a plurality of points symmetrical to the center point of the cathode 101. For example, the position symmetrical to the center point of the cathode 101 may be set to a plurality of input positions of the DC power and/or the high frequency power.

The magnetic field generator 102 formed by a permanent magnet and an electromagnet is positioned and located at the rear of the cathode 101, and can expose the surface of the target 11 to a magnetic field 103. While the magnetic field 103 preferably does not reach up to the surface of the substrate 12, if it is to the extent of not narrowing an extensive single-crystal domain of the boron lanthanum compound, the magnetic field 103 may reach the surface of the substrate 12.

An HF cut filter 24 provided at the side of the first DC power source 194 used in the present invention can protect the first DC power source 194 as another effect.

A south pole and a north pole of the magnetic field generating means 102 can be mutually disposed as a opposite polarity in a vertical direction to the flat surface of the cathode 103. At this time, adjacent magnets are made mutually into a opposite polarity in a horizontal direction to the flat surface of the cathode 103. Further, the south pole and the north pole of the magnetic field generating means 102 can also be mutually disposed as a opposite polarity in the horizontal direction to the flat surface of the cathode 103. At this time also, the adjacent magnets are mutually made into a opposite polarity in the horizontal direction to the flat surface of the cathode 103.

In the preferred mode of the present invention, the magnetic field generating means 102 can perform a reciprocation motion in the horizontal direction to the cathode 101 or the surface of the target 11.

The filter 23 used in the present invention can cut a low frequency component (0.01 MHz or less, particularly, the frequency component 0.001 MHz or less) from the high frequency power source 193.

Further, the present invention can extend an average area of the single-crystal domain by applying the DC power (voltage) from the second DC power source 21 of the substrate 12 side to the substrate holder 13. This second DC power (voltage) may be a pulse waveform power having a DC component (DC component to the ground) in an hourly average.

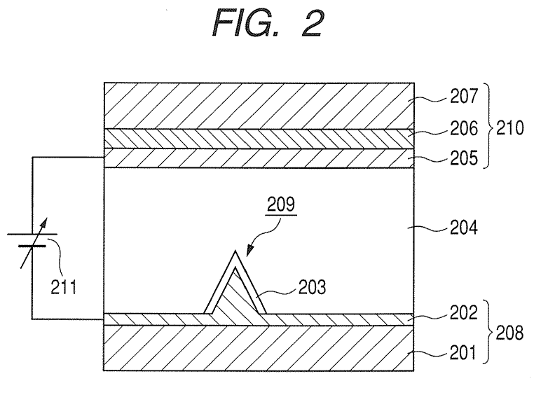

In FIG. 2, reference numeral 208 denotes an electron source substrate having a molybdenum film (cathode electrode) 202 formed a cone-shaped projection 209 (Spindt-type electron emitting base member), and a LaB₆ film 203 coating the projection 209 of the molybdenum film. Reference numeral 210 denotes a phosphor substrate made of a glass substrate 207, a phosphor film 206 thereon, and an anode electrode 204 made of a thin aluminum film. A space 204 between these electron source substrate 208 and phosphor substrate 210 is a vacuum space. By applying a DC voltage of 100 V to 3000 V between the cathode electrode 202 and an anode electrode 205, an electron beam is irradiated from the top end of the projection 209 of the molybdenum film 202 coated by the LaB₆ film 203 to the anode electrode 205, and the electron beam transmits the anode electrode 205, and there, it collides against the phosphor film, so that the phosphor can be made to emit light.

In the present invention, as the electron emitting base member, it is not limited to the above described, and in addition, it may be a SED type electron emitting base member using the thin film (PdO thin film, crystal carbon thin film, and the like) forming a nano scale gap by a forming process.

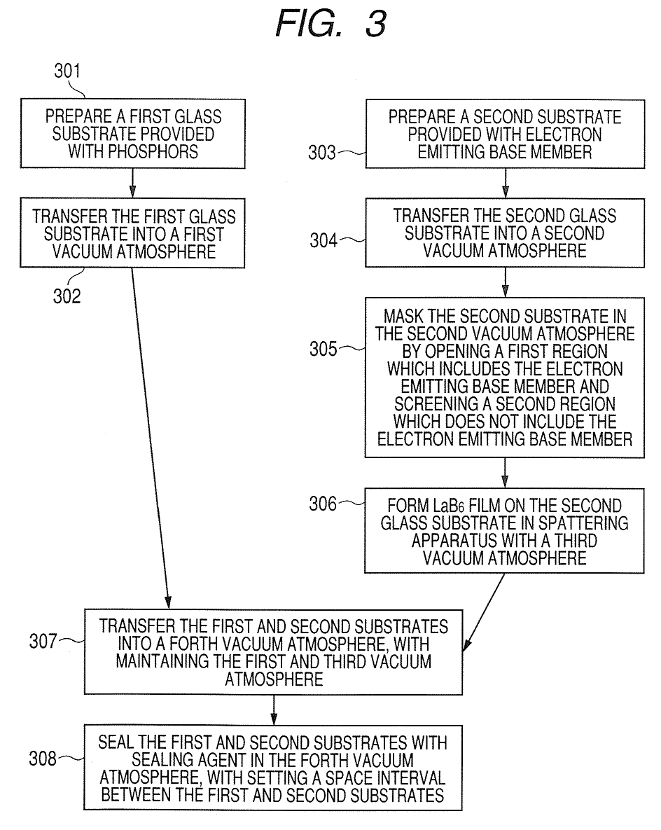

FIG. 3 is a view showing a flowchart of the present invention. A step 301 is a step to prepare a first glass substrate provided with a phosphor film which emits a phosphor light when an irradiation of electron is received. A phosphor layer is disposed with phosphors of three kinds for emitting a red fluorescence, a green fluorescence, and a blue fluorescence. While the red phosphor, the green phosphor, and the blue phosphor are linearly disposed in the signal line direction of a matrix wiring made of the scan line and the signal line, the disposition of the phosphors is not limited to this. To the glass substrate, it is possible to dispose a conductive film (an aluminum film, a titanium film, a barium film, and the like) serving as an anode electrode for accelerating the electron from the electron source, a black matrix body (for example, a black resin matrix, a metal matrix, and the like) for partitioning the pixel, and a spacer, and the like.

A step 302 is a step in which the first glass substrate is transferred into a first vacuum chamber forming a first vacuum or reduced pressure atmosphere (hereinafter, both of “vacuum” and “reduced pressure atmosphere” are referred to as “vacuum”). At the time of transferring, an ordinary load lock chamber (not shown) and a gate valve (not shown) can be used.

A step 303 is a step in which a second glass substrate provided with the electron emitting base member is prepared. This electron emitting base member is disposed at an intersecting point with the scan line and the signal line on an equivalent circuit, and is provided for a matrix drive. While the electron emitting base member has an electron emission effect by itself, its electron emission efficiency can be improved to a large extent by the low work function substance film of the later step.

The electron emitting base member of one section together with the phosphor film of one section forms one sub-pixel. Three color pixels of one red sub-pixel, one green sub-pixel and one blue sub-pixel form one-pixel. In the present invention, the one-pixel is disposed at a plurality of columns along a plurality of rows, thereby a matrix-array can be formed. In this matrix array, a metal film wiring (aluminum wiring, copper wiring, silver wiring, and the like) for the scan line and a metal film wiring (aluminum wiring, copper wiring, silver wiring, and the like) for the signal line are formed.

Further, to the second glass substrate used in the present invention, an antistatic film (charge dissipation film) for charging an electrostatic charge generated during a manufacturing step or the operation as a display device can be preferably provided. As this antistatic film, a titanium oxide film, a tin oxide film, an indium oxide film, an indium/tin oxide film (ITO film), and the like can be used.

Further, the second glass substrate used in the present invention can also be provided with a spacer and a sealing agent in advance.

In a step 304, the second glass substrate is transferred into the second vacuum chamber of a second vacuum atmosphere. At the time of transferring, a known load lock chamber (not shown) and gate valve (not shown) can be used.

A step 305 is a step in which the second glass substrate is provided with a mask 52 of FIG. 5 inside the second vacuum chamber of the second vacuum atmosphere. The mask 52 opens a first region including the electron emitting base member, and screens a second region not including the electron emitting base member. By using this mask 52, the second glass substrate is masked.

As the mask 52, while a stainless mask and an aluminum mask are preferably used, it is not limited to them.

In order to maintain airtightness with the second glass substrate, it is possible to apply a vacuum chuck mechanism and an electrostatic chuck mechanism to the mask 52.

A step 306 is a step in which a boron lanthanum compound film such as LaB₆ is provided on the second glass substrate by using a sputtering apparatus (magnetron sputtering apparatus, high frequency RF magnetron sputtering apparatus, and the like shown in FIG. 1) using a third chamber of a third vacuum atmosphere. Prior to this step, the second glass substrate is transferred into the sputtering apparatus in a state in which the vacuum is maintained by a load lock chamber (not shown) and a gate valve (not shown).

By the step 306, the boron lanthanum compound film such as LaB₆ is located entirely or partially of the second glass substrate, and as a result, the electron emitting base member is coated by the boron lanthanum compound film such as LaB₆ which is the low work function substance film, and the mask is isolated and removed from the second glass substrate.

An LaB₆ film is not formed on The second region not including the electron emitting base member. As a result, at the time of displaying, an unnecessary light emission due to the electron generated from the LaB₆ film of the second region, which becomes an unnecessary electron source other than the pixel, does not occur. Hence, display of high display quality having no reduction in display contrast and no flickering light caused by this can be obtained.

Further, in addition, the present invention can use, for example, a CeB₆ film, a BaLaB₆ film, a carbon containing LaB₆ film, and the like as a low work function substance film.

In a step 307, the first glass substrate of the step 302 and the second glass substrate of the step 306 are transferred into a fourth chamber of a fourth vacuum atmosphere while maintaining each glass substrate in a vacuum state. The first vacuum atmosphere, the third vacuum atmosphere, and the fourth vacuum atmosphere are vacuum-connected by a gate valve (not shown).

In a step 308, the first glass substrate and the second glass substrate are oppositely placed at the predetermined interval inside the fourth chamber, the position of the phosphor film of one section and the position of the electron emitting base member of one section are matched accurately, and they are sealed by using a sealing agent. The predetermined interval is decided by the spacer provided in advance. The spacer may be column-like or plate-like, and is disposed at every predetermined interval. The sealing agent is provided at the first glass substrate or the second glass substrate in advance, and can be sealed to form a vacuum atmosphere between the first glass substrate and the second glass substrate. As the sealing agent, a low melting point metal (for example, iridium and tin) and an organic resin adhesive, and the like can be preferably used.

In the step 308, the first glass substrate and the second glass substrate are held by the known electrostatic chuck and vacuum chuck, and in a state in which both substrates are spaced at a sufficient distance, they are subjected to vacuum bake processing and can be adhered with a gettering material such as barium and titan. After that, both substrates are made close to the interval decided by the spacer material, and after that, are subjected to the sealing work processing, thereby a vacuum display panel is manufactured.

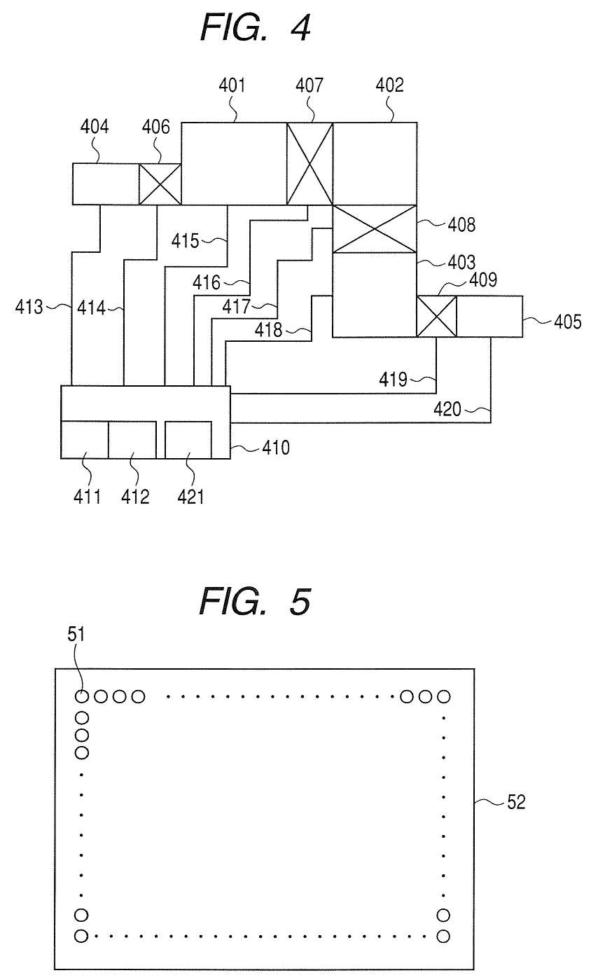

FIG. 4 is a block diagram of the present invention. Reference numeral 401 denotes a vacuum mask loading chamber for performing the steps 304 and 305, reference numeral 402 a magnetron sputtering apparatus for performing the step 306, reference numeral 403 an assemble device in vacuum space for performing the steps 307 and 308, reference numerals 404 and 405 first and second load lock chambers, reference numerals 406, 407, 408, and 409 gate valves, reference numeral 410 a computer, reference numeral 411 an arithmetic operation circuit unit, reference numeral 413 a memory unit, and reference numerals 414, 415, 416, 417, 418, and 419 a control bus line.

The first glass substrate provided with the phosphor film is transferred into the second load lock chamber 405, and after vacuum-exhausting the inside of the chamber 405, the gate valve 409 is opened, and is transferred into the chamber apparatus 403 for transferring phosphor substrate in vacuum atmosphere.

The second glass substrate provided with the electron emitting base member is transferred into the first load lock chamber 404, and after vacuum-exhausting the inside of the chamber 401, the gate valve 406 is opened, and the second glass substrate is positioned inside the vacuum chamber 401. The mask (illustrated in FIG. 5) 52 where opening is formed in a portion equivalent to the region including the electron emitting base member is disposed on the second glass substrate inside this chamber 401.

After completing the step 304, the gate valve 407 is opened, and in a state in which the mask 52 is held, the second glass substrate is transferred into the magnetron sputtering apparatus 402. The magnetron sputtering apparatus 402 performs the step 306, and can provide the LaB₆ film in the region including the electron emitting base member.

The computer 410 has a memory unit 421, and can control all the steps from the steps 301 to 308. As the memory unit 421, it is possible to use a recording medium such as a hard disc medium, a magneto-optic disc medium, and a floppy (registered trademark) disc medium, and a non-volatile memory (memory medium) such as a flash memory and an MRAM, and the memory unit 421 can temporarily memorize the data from the non-volatile memory. The memory unit 421 stores a control program for controlling all the steps from the steps 301 to 308. The stored control program data is processed by the arithmetic operation circuit unit (CPU: Central Arithmetic Circuit) 411, and these processed data are transmitted as illustrated through the control bus lines 413, 414, 415, 416, 417, 418, 419, and 420.

Further, in the present invention, a time control unit 412 (for example, generates a control signal by using a clock from a wave clock) is located inside the arithmetic operation circuit unit 411, so that all the steps 301 to 308 can be accurately controlled.

Further, in the present invention, as the magnet unit used in the magnetron sputtering, a permanent magnet which is commonly used can be used.

Further, when the magnetron sputtering is performed by stopping the movement of the tray, a target having an area slightly larger than the substrate 12 is prepared, and a plurality of magnet units are disposed on the rear surface of the target spaced at appropriate intervals, and they are made to perform a translation motion in the direction parallel to the target surface, so that good thickness uniformity and a high rate of target utilization can be obtained. Further, when performing the sputtering while moving the tray, with respect to the moving direction of the substrate, the target and the magnet unit having a short width as compared with a length of the substrate can be used.

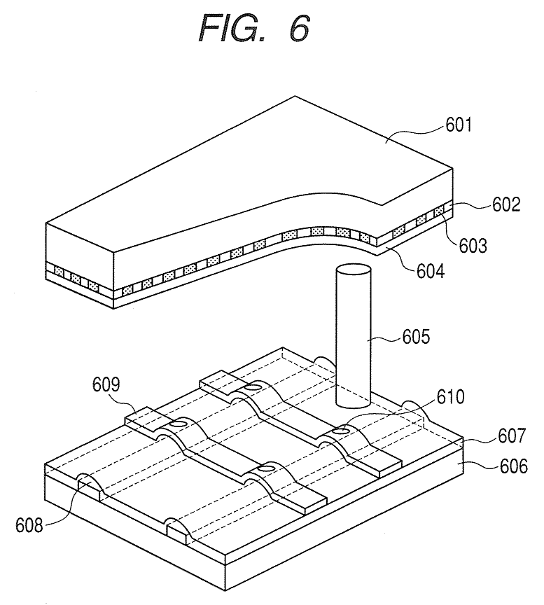

FIG. 6 is a schematic perspective view of the electron emitting device of one example obtained by the manufacturing method of the present invention. In FIG. 6, reference numeral 601 denotes a glass support substrate, and is a display-side substrate of the side from which the display is seen. The glass support substrate 601 is a three primary color phosphor matrix made of a red phosphor, a green phosphor, and a blue phosphor. The present invention is not limited to the three primary color, and other colors (for example, complementary color relation colors, orange color, yellowish green color, and the like) are further added to the three primary color. Reference numeral 603 denotes the black matrix. Reference numeral 604 denotes a metal film of aluminum, titan, barium, and the like serving as an anode electrode, and is applied with high voltage of 300 V to 2000 V, and is set to a film thickness that transmits the electron beam. Reference numeral 605 denotes a spacer for maintaining a vacuum thickness of the vacuum chamber. The spacer 605 is fabricated by glass, ceramic, oxide metal, metal, and the like. Further, the spacer may be plate-like in addition to being column-shaped as shown in FIG. 6. Reference numeral 606 denotes a rear face substrate, which may be formed by a ceramic material, a metal oxide material, and a metal material, though a glass material is preferable. Reference numeral 607 denotes an insulator film, which is formed by silicon oxide, titan oxide, and various kinds of insulating organic resins. Reference numeral 608 denotes a scan line, which uses various kinds of metals (for example, aluminum, copper, silver, and the like). Reference numeral 609 denotes a signal line, which can be formed by various kinds of metals (for example, aluminum, copper, silver, and the like). A scan line 608 and a signal line 609 are interlayer-insulated by the insulator film 607. Reference numeral 610 is a hole containing the electron emitting device. The electron emitting device shown in FIG. 2 is disposed inside the hole 610. Further, inside the hole, not only the Spindt-type electron emitting device shown in FIG. 2, but also the SCE type electron emitting device may be disposed.

The scan line 608 and the signal line 609 are matrix-driven by a scan side drive circuit (not shown) and a signal side drive circuit (not shown), respectively. This matrix-drive is such that a scan signal is applied to the scan line 608 and an image signal synchronized with the scan signal is applied to the signal line 609, thereby displaying an image.

1. A manufacturing method of an electron emitting device, comprising:
a first step of preparing a first substrate disposed with phosphors and disposing it in a vacuum or reduced pressure atmosphere;
a second step of preparing a second substrate provided with an electron emitting base member and disposing the second substrate in a vacuum or reduced pressure atmosphere;
a third step of disposing a mask for opening a first region including said electron emitting base member and screening a second region not including said electron emitting base member, in a state in which a vacuum or reduced pressure atmosphere is maintained from said second step;
a fourth step of accumulating sputtered particles on the second substrate subjected to said second step by a sputtering method using a target having a low work function substance in a state in which the vacuum or reduced pressure atmosphere is maintained from said third step; and
a fifth step of arranging the first substrate subjected to said first step opposite the second substrate subjected to said fourth step and sealing the first substrate and the second substrate by a sealing agent to fabricate a vacuum or reduced pressure chamber, in a state in which the vacuum or reduced pressure atmosphere is maintained from said first step and said fourth step.

2. The manufacturing method according to claim 1, wherein said electron emitting base member is a Spindt-type electron emitting device.

3. The manufacturing method according to claim 1, wherein said target includes a sintered body containing a boron atom (B) and a lanthanum atom (La).

4. The manufacturing method according to claim 1, wherein a sediment of said fourth step includes a crystalline sediment containing a boron atom (B) and a lanthanum atom (La).

5. A memory medium for the manufacturing of an electron emitting device, comprising a control program for executing:
a first step of preparing a first substrate disposed with phosphors and disposing it in a vacuum or reduced pressure atmosphere;
a second step of preparing a second substrate provided with an electron emitting base member and disposing the second substrate in a vacuum or reduced pressure atmosphere;
a third step of disposing a mask for opening a first region including said electron emitting base member and screening a second region not including said electron emitting base member, in a state in which a vacuum or reduced pressure atmosphere is maintained from said second step;
a fourth step of accumulating sputtered particles on the second substrate subjected to said second step by a sputtering method using a target having a low work function substance in a state in which the vacuum or reduced pressure atmosphere is maintained from said third step; and
a fifth step of arranging the first substrate subjected to said first step opposite the second substrate subjected to said fourth step and sealing the first substrate and the second substrate by a sealing agent to fabricate a vacuum or reduced pressure chamber, in a state in which the vacuum or reduced pressure atmosphere is maintained from said first step and said fourth step.

6. The memory medium according to claim 5, wherein said electron emitting base member is a Spindt-type electron emitting device.

7. The memory medium according to claim 5, wherein said target includes a sintered body containing a boron atom (B) a the lanthanum atom (La).

8. The memory medium according to claim 5, wherein a sediment of said fourth step includes a crystalline sediment containing a boron atom(B)and a lanthanum atom (La).

9. A recording medium for the manufacturing of an electron emitting device, comprising a control program for executing:
a first step of preparing a first substrate disposed with phosphors and disposing it in a vacuum or reduced pressure atmosphere;
a second step of preparing a second substrate provided with an electron emitting base member and disposing the second substrate in a vacuum or reduced pressure atmosphere;
a third step of disposing a mask for opening a first region including said electron emitting base member and screening a second region not including said electron emitting base member, in a state in which a vacuum or reduced pressure atmosphere is maintained from said second step;
a fourth step of accumulating sputtered particles on the second substrate subjected to said second step by a sputtering method using a target having a low work function substance in a state in which the vacuum or reduced pressure atmosphere is maintained from said third step; and
a fifth step of arranging the first substrate subjected to said first step opposite the second substrate subjected to said fourth step and sealing the first substrate and the second substrate by a sealing agent to fabricate a vacuum or reduced pressure chamber, in a state in which the vacuum or reduced pressure atmosphere is maintained from said first step and said fourth step.

10. The recording medium according to claim 9, wherein said electron emitting base member is the Spindt-type electron emitting device.

11. The recording medium according to claim 9, wherein said target includes a sintered body containing a boron atom (B) and a lanthanum atom (La).

12. The recording medium according to claim 9, wherein a sediment of said fourth step includes a crystalline sediment containing a boron atom (B) and a lanthanum atom (La).
